(19) United States
(12) Patent Application Publication
(10) Pub. No.: US 2026/0352204 A1
(43) Pub. Date: Nov. 5, 2026

(54) Power On Reset Circuit

(71) Applicant: Mitsubishi Electric Corporation, Chiyoda-ku Tokyo (JP)

(72) Inventor: Tomokazu KOJIMA, Chiyoda-ku, Tokyo (JP)

(73) Assignee: Mitsubishi Electric Corporation, Chiyoda-ku Tokyo (JP)

(21) Appl. No.: 19/118,849

(22) PCT Filed: Dec. 19, 2022
(86) PCT No.: PCT/JP2022/046664

§ 371 Date: Apr. 7, 2025

(51) Int. Cl. H03K 17/22

(52) U.S. Cl. CPC H03K 17/223

(57) ABSTRACT

A voltage dividing circuit outputs a divided voltage of a supply voltage to a first node. A voltage rate detection circuit detects a voltage change rate of the supply voltage at the time of rise of the supply voltage. A voltage determination circuit generates an output signal indicating a result of comparison between a voltage of the first node and a predetermined threshold voltage. The voltage dividing circuit is configured to maintain a voltage division ratio constant in accordance with the voltage change rate detected by the voltage rate detection circuit and to variably set an impedance between a power supply line and a reference voltage line. The impedance of the voltage dividing circuit is set to be lower as the voltage change rate is higher.

### TECHNICAL FIELD

The present disclosure relates to a power on reset circuit.

### BACKGROUND ART

At the time of start of supply of a supply voltage to a semiconductor device, if the semiconductor device starts operating in a stage in which the supply voltage is not at a sufficient level, specifically, in a stage in which a voltage is low to such an extent that a transistor cannot be turned on, a malfunction may occur.

Therefore, a power on reset circuit to sense that a supply voltage is equal to or higher a certain level and to generate a power on reset (POR) signal has conventionally been used. A semiconductor device can be prevented from malfunctioning by starting operations after the POR signal is generated.

For example, Japanese Patent Laying-Open No. 2019-186943 (PTL 1) describes a power on reset circuit low in consumption current. In the power on reset circuit described in PTL 1, when a voltage detector 115 detects a supply voltage becoming higher than a threshold voltage level (VPOR_R) at the time of rise of the supply voltage, an output signal from voltage detector 115 is held by a POR latch 120 and a POR signal is generated. After the supply voltage becomes higher, voltage detector 115 is turned off, so that power consumption can be suppressed.

Furthermore, according to PTL 1, as shown in FIGS. 2A and 2B, an adjustable resistor (R1, R2) is arranged in a supply voltage (V_BUS) divider circuit, and the threshold voltage level (VPOR_R) of the power on reset circuit is determined by changing a resistance value of the adjustable resistor.

### CITATION LIST

### Patent Literature

PTL 1: Japanese Patent Laying-Open No. 2019-186943

### SUMMARY OF INVENTION

### Technical Problem

Application of energy harvesting to convert natural energy represented by sunlight into electric power has recently been extended. In using an energy harvesting power supply, depending on change of an environment (for example, luminous intensity of light to photovoltaic cells), each time the supply voltage rises, a voltage change rate and a duration of supply of a voltage are assumed to variously change. Therefore, generation of a POR signal at appropriate timing in accordance with various voltage change rates (rates of increase) even when the voltage change rate is different each time of rise of the supply voltage is an issue.

In particular, in an application in which a POR signal is appropriately generated to activate a semiconductor device in correspondence with supply of power for a relatively short period, represented by a wireless sensor network which operates at the time when power supply is obtained by energy harvesting, generation of the POR signal at appropriate timing without delay when a rate of change in supply voltage is high is demanded.

In the power on reset circuit described in PTL 1, the resistance value of the adjustable resistor (R1, R2) can be adapted in accordance with an assumed slew rate of the supply voltage. Change of the slew rate of the supply voltage each time of rise of the supply voltage, however, is not assumed.

Furthermore, in the power on reset circuit in PTL 1, in order to turn off voltage detector 115 including the voltage divider circuit for the purpose of reduction in power consumption, a transistor connected in series to the voltage divider circuit and latch 120 in a subsequent stage should be arranged. Therefore, there is a concern about delay in generation of the POR signal when the supply voltage rises at a high rate.

The present disclosure was made to solve such problems, and an object of the present disclosure is to provide a power on reset circuit appropriately operable in spite of change of a voltage change rate at the time of rise of a supply voltage, with power consumption being suppressed.

### Solution To Problem

According to one aspect of the present disclosure, a power on reset circuit includes a power supply line supplied with a supply voltage, a reference voltage line through which a reference voltage is transmitted, a voltage dividing circuit, a voltage rate detection circuit, and a voltage determination circuit. The voltage dividing circuit is connected between the power supply line and the reference voltage to output a divided voltage of the supply voltage on the power supply line to a first node. The voltage rate detection circuit detects a voltage change rate of the supply voltage at the time of rise of the supply voltage. The voltage determination circuit generates an output signal indicating a result of comparison between a voltage of the first node and a predetermined voltage. The voltage dividing circuit is configured to maintain constant, a voltage division ratio of the divided voltage to the supply voltage and to variably set an impedance between the power supply line and the reference voltage, in accordance with the voltage change rate detected by the voltage rate detection circuit. This impedance is set to be lower as the voltage change rate is higher.

### Advantageous Effects Of Invention

According to the present disclosure, a power on reset circuit appropriately operable in spite of change of a voltage change rate at the time of rise of a supply voltage, with power consumption being suppressed by appropriate change of an impedance of the voltage dividing circuit in accordance with the voltage change rate at the time of rise of the supply voltage, can be provided.

### BRIEF DESCRIPTION OF DRAWINGS

FIG. 1 is a circuit diagram illustrating a configuration of a power on reset circuit according to a comparative example.

FIG. 2 is a conceptual operation waveform diagram of a power on reset circuit at the time of rise of a supply voltage.

FIG. 3 is a block diagram illustrating a configuration of a power on reset circuit according to a first embodiment.

FIG. 4 is a circuit diagram illustrating an exemplary configuration of a voltage dividing circuit in FIG. 3.

FIG. 5 is a circuit diagram illustrating an exemplary configuration of a voltage determination circuit in FIG. 3.

FIG. 6 is an equivalent circuit diagram of the power on reset circuit according to the first embodiment.

FIG. 7 is a circuit diagram illustrating an exemplary configuration of a voltage rate detection circuit according to a second embodiment.

FIG. 8 is a conceptual waveform diagram illustrating an operation of the voltage rate detection circuit shown in FIG. 7.

FIG. 9 is a chart illustrating the operation of the voltage rate detection circuit shown in FIG. 7.

FIG. 10 is a circuit diagram illustrating an exemplary configuration of a voltage determination circuit according to a third embodiment.

FIG. 11 is a circuit diagram illustrating an exemplary configuration of a voltage rate detection circuit according to the third embodiment.

FIG. 12 is a conceptual operation waveform diagram at the time of rise of the supply voltage of the power on reset circuit according to the first embodiment.

### DESCRIPTION OF EMBODIMENTS

An embodiment of the present disclosure will be described in detail below with reference to the drawings. The same or corresponding elements in the drawings have the same reference characters allotted and description thereof will not be repeated in principle.

### First Embodiment

Prior to description of a power on reset circuit according to a first embodiment, a comparative example will be described.

### Description of Comparative Example

FIG. 1 is a circuit diagram illustrating a configuration of a power on reset circuit 5# according to the comparative example.

As shown in FIG. 1, power on reset circuit 5# includes a voltage dividing circuit 10# and a voltage determination circuit 20#.

Voltage dividing circuit 10# includes resistive elements RH and RL connected in series between a power supply line PL supplied with a supply voltage AVDD and a reference voltage line NL through which a reference voltage VSS is transmitted. Since reference voltage VSS is representatively ground (a ground voltage), reference voltage VSS will also be referred to as a ground voltage VSS below and reference voltage line NL will also be referred to as a ground line NL below.

Resistive element RH is connected between power supply line PL and a node N1 and resistive element RL is connected between node N1 and ground line NL. Therefore, at node N1, a divided voltage Vdiv of supply voltage AVDD resulting from resistive elements RH and RL is produced.

An electrical resistance value of each resistive element will also herein be expressed with the same reference character below. Therefore, an expression (1) below holds for divided voltage Vdiv and supply voltage AVDD. Specifically, a voltage division ratio Kv of voltage dividing circuit 10# is expressed as Kv=RL/(RL+RH) (Kv<1).

Vdiv=Kv●AVDD . . . (1)

Voltage determination circuit 20# includes a transistor 21, a current supply circuit 22, and a signal generation circuit 25 implemented by an inverter.

Transistor 21 is implemented by an N-type field effect transistor, it is connected between a node N2 and ground line NL, and it has a gate (control electrode) connected to node N1. Current supply circuit 22 includes a resistive element RD connected between power supply line PL and node N2. Signal generation circuit 25 outputs an output signal VPOR having a logic level in accordance with a voltage Vdet of node N2. Output signal VPOR corresponds to what is called a power on reset signal (POR signal).

In the example in FIG. 1 where signal generation circuit 25 is implemented by the inverter, when voltage Vdet lowers to ground voltage VSS in response to turn-on of transistor 21, output signal VPOR is set to a logic high level (which will be referred to as an “H level” below). While transistor 21 is off, on the other hand, in response to pull-up of node N2 to supply voltage AVDD, output signal VPOR is set to a logic low level (which will be referred to as an “L level” below). In connection with a threshold voltage Vt1 of transistor 21, when a condition of Vdiv≥Vt1 is satisfied, transistor 21 turns off, and when a condition of Vdiv>Vt1 is satisfied, transistor 21 turns on.

Therefore, when supply voltage AVDD rises from ground voltage VSS at the time of activation of a semiconductor device on which the power on reset circuit is mounted, output signal VPOR is at the L level (ground voltage VSS) while the condition of Vdiv≤Vt1 is satisfied, and output signal VPOR is at the H level (supply voltage AVDD) while the condition of Vdiv>Vt1 is satisfied. Consequently, whether or not supply voltage AVDD is higher than a criterion voltage Vpr corresponding to (Vt1/Kv) can be determined based on output signal VPOR. By adjusting voltage division ratio Kv such that criterion voltage Vpr is compatible with a lower limit voltage at which operations of the semiconductor device can be guaranteed, output signal VPOR can be used as the POR signal indicating permission of start of operations of each circuit mounted on the semiconductor device.

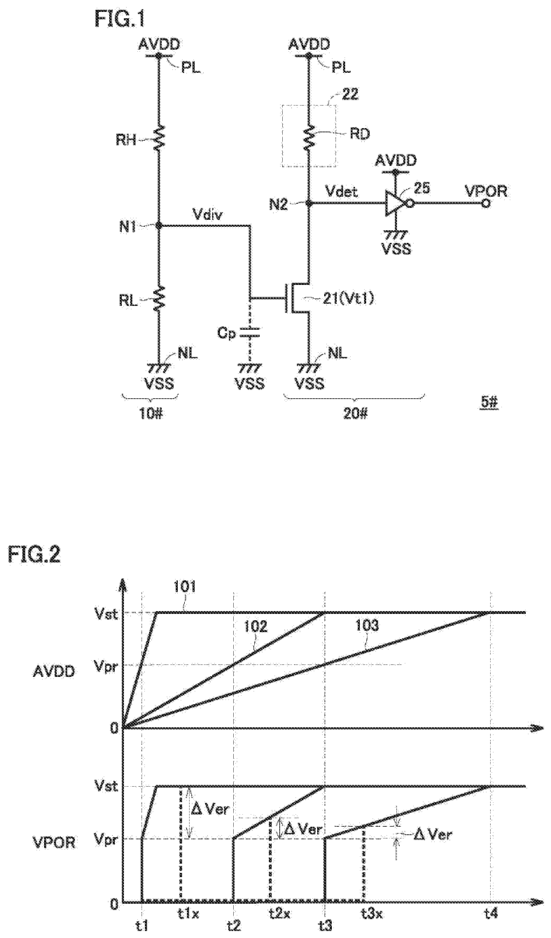

FIG. 2 shows a conceptual operation waveform diagram of the power on reset circuit at the time of rise of the supply voltage.

FIG. 2 shows waveforms 101~103 at the time of rise of supply voltage AVDD. Waveforms 101~103 are different in voltage change rate (dAVDD/dt) at the time of rise. In an example where supply voltage AVDD is supplied from output from photovoltaic cells, there is a difference in voltage change rate depending on difference in amount of light reception by the photovoltaic cells. Therefore, there is a difference among waveforms 101~103 in timing of supply voltage AVDD reaching a rated value Vst.

Similarly, there is a difference among waveforms 101~103 also in timing of supply voltage AVDD reaching above-described criterion voltage Vpr. In waveform 101, supply voltage AVDD reaches criterion voltage Vpr at time t1. In waveform 102, supply voltage AVDD reaches criterion voltage Vpr at time t2 later than time t1. In waveform 103, supply voltage AVDD reaches criterion voltage Vpr at time t3 later than time t2.

In power on reset circuit 5#, at the timing when supply voltage AVDD reaches criterion voltage Vpr, divided voltage Vdiv reaches threshold voltage Vt1 of transistor 21. Therefore, ideally, as transistor 21 turns on at each of times t1~t3 as shown with a solid line in FIG. 2, output signal VPOR makes transition from the L level (ground voltage VSS) to the H level (supply voltage AVDD).

As shown with a dotted line in FIG. 1, however, at node N1, there is a parasitic capacitance Cp such as a gate capacitance of transistor 21. Therefore, timing of turn-on of transistor 21 is delayed from times t1~t3 to times t1x~t3x due to a time period for charging of parasitic capacitance Cp. Consequently, output signal VPOR actually makes transition from the L level to the H level at times t1x~t3x later than times t1~t3, as shown with the dotted line.

It is understood here that a voltage error ΔVer between supply voltage AVDD and criterion voltage Vpr at the time when output signal VPOR actually makes transition to the H level varies depending on the voltage change rate in each of waveforms 101~103. Specifically, as the voltage change rate is higher, voltage error ΔVer becomes greater.

Consequently, there is a concern about delay in start of operations of the semiconductor device in accordance with output signal VPOR. In particular, in an application of an energy harvesting power supply, it is also assumed that supply of supply voltage AVDD is sporadic and lasts for a short period of time. Therefore, there is a concern about lowering in performance of the semiconductor device if start of operations is delayed in such a case.

The time of delay from times t1~t3 until times t1x~t3x is mainly determined by an RC time constant in accordance with a product of an R component resulting from voltage dividing circuit 10# and parasitic capacitance Cp. Therefore, as a resistance value (RH+RL) in voltage dividing circuit 10# is decreased, a charging current for charging parasitic capacitance Cp becomes larger and hence time of delay determined by the RC time constant can be shorter. In other words, an operation speed of power on reset circuit 5# can be enhanced.

Decrease in resistance value (RH+RL), however, leads to increase in current steadily produced between power supply line PL and ground line NL in voltage dividing circuit 10#. In the configuration in FIG. 1, output signal VPOR (POR signal) can be generated quickly without the transistor connected in series to the voltage divider circuit and the latch circuit in the subsequent stage as in PTL 1, whereas the steady current is steadily produced while supply voltage AVDD is supplied. Consequently, in power on reset circuit 5#, in voltage dividing circuit 10#, with decrease in resistance value (RH+RL), an operation speed increases whereas power consumption increases, and with increase in resistance value (RH+RL), power consumption lowers whereas the operation speed lowers.

A rate of change of voltage Vdet of node N2 to ground voltage VSS at the time of turn-on of transistor 21 is affected by magnitude of a supply current supplied by current supply circuit 22. In the example in FIG. 2, as resistance value RD is smaller, the supply current increases and voltage Vdet can quickly change to ground voltage VSS. Consequently, timing of transition of output signal VPOR to the H level can be advanced and the time of delay from times t1~t3 to times t1x~t3x can be shorter. In other words, an operation speed of power on reset circuit 5# can be enhanced.

Transistor 21, on the other hand, is maintained in an on state while output signal VPOR is at the H level. Therefore, in the presence of resistive element RD and transistor 21 (on state), a steady current is produced between power supply line PL and ground line NL also in voltage determination circuit 20#. Consequently, in power on reset circuit 5# in FIG. 1, also in voltage determination circuit 20#, with decrease in resistance value RD, the operation speed increases whereas power consumption increases, and with increase in resistance value RD, power consumption lowers whereas the operation speed lowers.

### Power On Reset Circuit According to First Embodiment

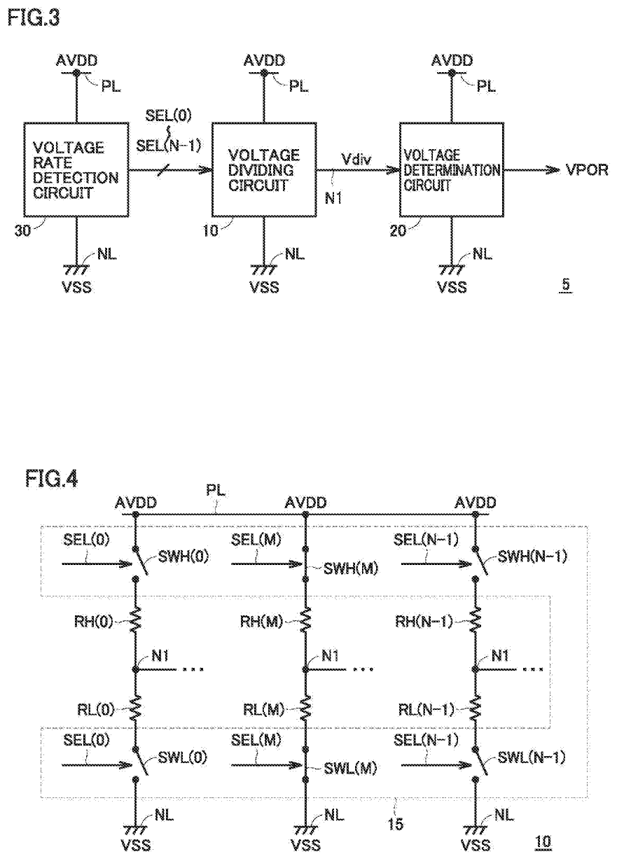

FIG. 3 is a block diagram illustrating a configuration of a power on reset circuit 5 according to the present embodiment.

As shown in FIG. 3, power on reset circuit 5 includes a voltage dividing circuit 10, a voltage determination circuit 20, and a voltage rate detection circuit 30 which are connected between power supply line PL and ground line NL. Voltage dividing circuit 10 outputs divided voltage Vdiv of supply voltage AVDD on power supply line PL to node N1. Voltage determination circuit 20 generates output signal VPOR indicating a result of comparison between the voltage of node N1 and a predetermined threshold voltage (for example, threshold voltage Vt1 of transistor 21). In other words, node N1 corresponds to a “first node.”

Voltage rate detection circuit 30 detects a rate of change of the voltage on power supply line PL (that is, dAVDD/dt) at the time of rise of supply voltage AVDD, for example, with a differentiation circuit implemented by a capacitor. In the example in FIG. 3, voltage rate detection circuit 30 determines a voltage change rate VRT [V/s] in predetermined N stages (N: an integer not smaller than two) and sets any one of selection signals SEL(0)~SEL(N−1) to the H level in accordance with a result of determination.

In distinguishing herein between signals, between circuit elements, and the like in correspondence with the N stages, N signals, N circuit elements, and the like will be denoted with a number in parentheses being added. In general denotation of these N signals, N circuit elements, and the like, on the other hand, a number in parentheses will not be added.

When voltage change rate VRT is at the highest level among the N stages, selection signal SEL(N−1) is set to the H level and remaining SEL(0)~SEL(N−2) are set to the L level.

In contrast, when voltage change rate VRT is at the lowest level among the N stages, selection signal SEL(0) is set to the H level and remaining SEL(1)~SEL(N−1) are set to the L level. Thus, as voltage change rate VRT is lower, one selection signal on a lower-order bit side (a smaller i side) among selection signals SEL(i) corresponding to integers represented as i=0~(N−1) is set to the H level. In other words, as voltage change rate VRT is higher, one selection signal on a higher-order bit side (a larger i side) among selection signals SEL(i) is set to the H level. An exemplary preferred configuration of voltage rate detection circuit 30 will be described in detail in a second embodiment.

FIG. 4 shows a circuit diagram illustrating an exemplary configuration of voltage dividing circuit 10 in FIG. 3.

Referring to FIG. 4, voltage dividing circuit 10 includes N voltage division resistors connected in parallel between power supply line PL and ground line NL and a selection circuit 15.

The N voltage division resistors include resistive elements RH(0)~RH(N−1) connected between power supply line PL and node N1 and resistive elements RL(0)~RL(N−1) connected between node N1 and ground line NL, respectively. FIG. 4 shows resistive elements RH(0) and RL(0) which implement a voltage division resistor on a lowest-order bit side, resistive elements RH(N−1) and RL(N−1) which implement a voltage division resistor on a highest-order bit side, and resistive elements RH(M) and RL(M) which implement a voltage division resistor of an intermediate bit (0<M<(N−1)).

The N voltage division resistors are equal in voltage division ratio Kv, that is, ratio between resistance values of respective resistive elements RH(0)~RH(N−1) and respective resistive elements RL(0)~RL(N−1). In other words, a condition of RH(0): RL(0)=. . . =RH(M):RL(M)=. . . =RH(N−1):RL(N−1) is satisfied.

The N voltage division resistors, on the other hand, are different in sum of the resistance values of respective resistive elements RH(0)~RH(N−1) and the resistance values of respective resistive elements RL(0)~RL(N−1), that is, different in impedance between power supply line PL and ground line NL. Specifically, a condition of RH(0)+RL(0)>. . . >RH(M)+RL(M)>. . . >RH(N−1)+RL(N−1) is satisfied.

Selection circuit 15 includes switch elements SWH(0)~SWH(N−1) and switch elements SWL(0)~SWL(N−1). Switch elements SWH(0)~SWH(N−1) are connected in series to respective resistive elements RH(0)~RH(N−1), between power supply line PL and node N1.

Similarly, switch elements SWL(0)~SWL(N−1) are connected in series to respective resistive elements RL(0)~RL(N−1), between ground line NL and node N1.

Switch elements SWH(0)~SWH(N−1) and switch elements SWL(0)~SWL(N−1) turn on and off in accordance with selection signals SEL(0)~SEL(N−1), respectively. Specifically, each of switch elements SWH(0)~SWH(N−1) and SWL(0)~SWL(N−1) turns on when corresponding selection signal SEL is at the H level, whereas it turns off when corresponding selection signal SEL is at the L level.

For example, when a condition of selection signal SEL(0)=the H level is satisfied, switch elements SWH(0) and SWL(0) turn on. Since other selection signals SEL(1)~SEL(N−1) are at the L level at this time, other switch elements SWH(1)~SWH(N−1) and SWL(1)~SWL(N−1) turn off.

As described above, voltage rate detection circuit 30 sets one of N selection signals SEL to the H level and sets remaining (N−1) selection signals to the L level in accordance with the voltage change rate of supply voltage AVDD. Switch element SWH and switch element SWL to which selection signal SEL set to the H level has been inputted thus turn on.

Consequently, in voltage dividing circuit 10, in accordance with the voltage rate detected by voltage rate detection circuit 30, one of the N voltage division resistors is selected and connected between power supply line PL and ground line NL. In other (N−1) voltage division resistors, on the other hand, corresponding switch elements SWH and SWL turn off and hence no current is produced between power supply line PL and ground line NL. Until voltage rate detection circuit 30 detects the voltage rate, switch elements SWH(0)~SWH(N−1) and SWL(0)~SWL(N−1) are all off.

In the example in FIG. 4, as voltage rate detection circuit 30 sets selection signal SEL(M) to the H level, switch elements SWH(M) and SWL(M) turn on and the voltage division resistor implemented by resistive elements RH(M) and RL(M) is selectively connected between power supply line PL and ground line NL.

In FIG. 4, each of resistive elements RH(0)~RH(N−1) corresponds to one example of the “second resistive element” and each of resistive elements RL(0)~RL(N−1) corresponds to one example of the “third resistive element.” Node N1 corresponds to one example of the “first node” as described above.

FIG. 5 shows a circuit diagram illustrating an exemplary configuration of voltage determination circuit 20 in FIG. 3.

Referring to FIG. 5, voltage determination circuit 20 is different from voltage determination circuit 20# shown in FIG. 1 in including a current control circuit 27 instead of current supply circuit 22. Current control circuit 27 includes resistive elements RD(0)~RD(N−1) and switch elements SWD(0)~SWD(N−1) connected in parallel between power supply line PL and node N2. Switch elements SWD(0)~SWD(N−1) are connected in series to respective resistive elements RD(0)~RD(N−1), between power supply line PL and node N2.

Switch elements SWD(0)~SWD(N−1) turn on and off in accordance with selection signals SEL(0)~SEL(N−1), respectively. Specifically, each of switch elements SWD(0)~SWD(N−1) turns on when corresponding selection signal SEL is at the H level, whereas it turns off when corresponding selection signal SEL is at the L level. Until voltage rate detection circuit 30 detects the voltage rate, switch elements SWD(0)~SWD(N−1) are all off.

In the example in FIG. 5, as voltage rate detection circuit 30 sets selection signal SEL(M) to the H level, switch element SWD(M) turns on and resistive element RD(M) is selectively connected between power supply line PL and node N2.

Resistive elements RD(0)~RD(N−1) are different in resistance value. Specifically, the resistance value is set to be larger on the lower-order bit side or to satisfy a condition of RD(0)>RD(1)>. . . RD(M) . . . >RD(N−1). Voltage determination circuit 20 is otherwise similar in configuration to voltage determination circuit 20# shown in FIG. 1.

In voltage determination circuit 20, as switch element SWD to which selection signal SEL set to the H level is inputted turns on, one of N resistive elements RD(0)~RD(N−1) different in resistance value is selected in accordance with the voltage rate detected by voltage rate detection circuit 30 and connected between power supply line PL and node N2.

Therefore, as selection signal SEL on the higher-order bit side is set to the H level as the voltage change rate detected by voltage rate detection circuit 30 is higher, the resistance value of resistive element RD connected between power supply line PL and node N2 becomes smaller. In other words, a supply current Idet from current control circuit 27 to node N2 becomes larger. A rate of change of the voltage of node N2 at the time of turn-on of transistor 21 can thus be increased.

As selection signal SEL on the lower-order bit side is set to the H level as the voltage change rate detected by voltage rate detection circuit 30 is lower, the resistance value of resistive element RD connected between power supply line PL and node N2 becomes larger. The steady current produced between power supply line PL and ground line NL while transistor 21 is on can thus be made smaller.

Thus, in voltage determination circuit 20, current control circuit 27 can variably control supply current Idet to become larger with increase in voltage change rate. In FIG. 5, resistive elements RD(0)~RD(N−1) correspond to one example of the “plurality of first resistive elements” and node N2 corresponds to one example of the “second node.” Switch elements SWD(0)~SWD(N−1) correspond to one example of the “plurality of switch elements” and transistor 21 corresponds to one example of the “first transistor.”

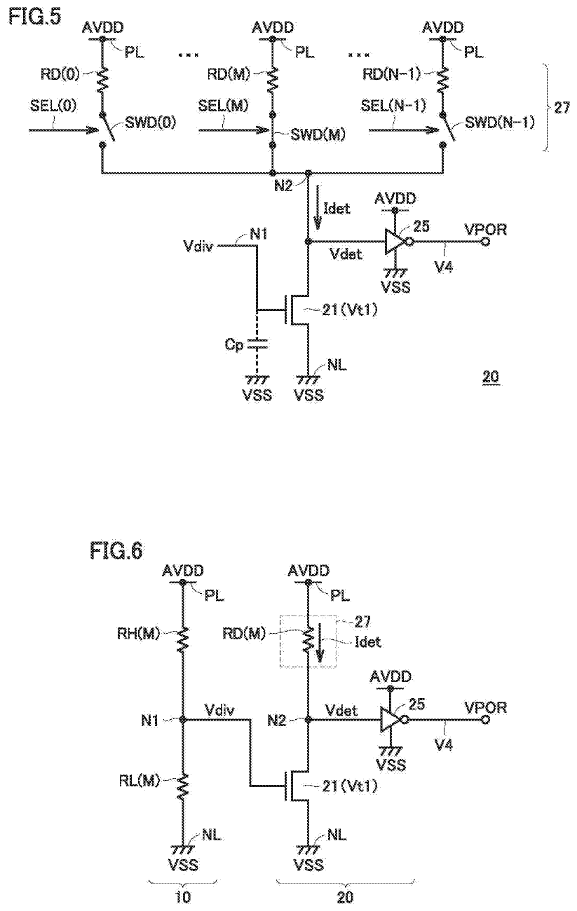

FIG. 6 is an equivalent circuit diagram of power on reset circuit 5 according to the first embodiment.

In FIG. 6, selection signal SEL(M) is set to the H level in accordance with the voltage change rate detected by voltage rate detection circuit 30. Consequently, in voltage dividing circuit 10, the voltage division resistor implemented by resistive elements RH(M) and RL(M) is connected between power supply line PL and ground line NL.

Thus, in accordance with the voltage change rate detected by voltage rate detection circuit 30, in voltage dividing circuit 10, voltage division ratio Kv is constant, whereas the voltage division resistor (RH and RL) is selected such that the impedance (resistance value) between power supply line PL and ground line NL is lower as the voltage change rate is higher, and in contrast, the impedance is higher as the voltage change rate is lower.

Therefore, according to power on reset circuit 5 according to the first embodiment, when the voltage change rate is high, the impedance between power supply line PL and ground line NL resulting from voltage dividing circuit 10 can be lowered. The operation speed can thus be increased by reducing time of delay until turn-on of transistor 21 at the time when supply voltage AVDD reaches criterion voltage Vpr (Vdiv>Vt1). When the voltage change rate is low, on the other hand, the impedance between power supply line PL and ground line NL resulting from voltage dividing circuit 10 can be increased to suppress the current steadily produced between power supply line PL and ground line NL and to reduce power consumption.

Furthermore, in voltage determination circuit 20, resistive element RD(M) is connected between power supply line PL and node N2 and supply current Idet in accordance with resistance value RD(M) is provided to node N2. Therefore, in voltage determination circuit 20, in accordance with the voltage change rate detected by voltage rate detection circuit 30, resistive element RD is selected such that supply current Idet is larger as the voltage change rate is higher and in contrast, supply current Idet is smaller as the voltage change rate is lower.

Consequently, in power on reset circuit 5 according to the first embodiment, the operation speed can further be increased by reducing a time period required until output signal VPOR makes transition from the L level to the H level at the time of turn-on of transistor 21 by increasing supply current Idet supplied under the control by current control circuit 27 when the voltage change rate is high. On the other hand, the current steadily produced between power supply line PL and ground line NL while transistor 21 is on can be suppressed and power consumption can be lowered by making supply current Idet supplied under the control by current control circuit 27 smaller when the voltage change rate is high.

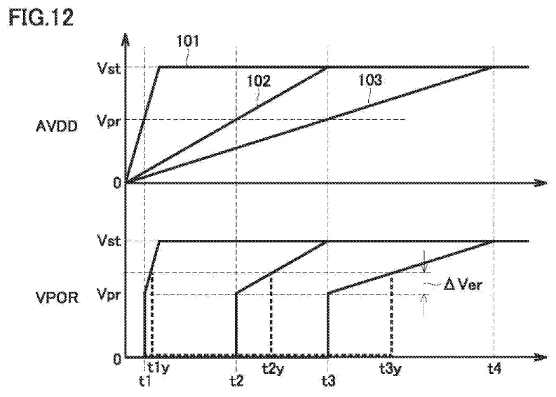

FIG. 12 shows a conceptual operation waveform diagram at the time of rise of the supply voltage of the power on reset circuit according to the first embodiment, to be compared with FIG. 2. FIG. 12 is similar to FIG. 2 also in waveforms 101~103 at the time of rise of supply voltage AVDD.

In power on reset circuit 5 according to the first embodiment as well, due to the time period required for detection of the voltage rate by voltage rate detection circuit 30 and the time period for charging of node N1 (parasitic capacitance Cp), in waveforms 101~103, timing of transition of output signal VPOR from the L level to the H level is times t1y~t3y later than times t1~t3, respectively.

In FIG. 12, mainly by changing the impedance of voltage dividing circuit 10 and further changing supply current Idet supplied under the control by current control circuit 27 in accordance with the voltage change rate, delay in time (for example, time t1~t1y) when the voltage change rate is high is shorter than in the comparative example in FIG. 2.

Though delay in time (for example, time t3~t3y) is longer when the voltage change rate is lower, it can be understood from comparison with FIG. 2 that voltage error ΔVer between supply voltage AVDD at the time of actual transition of output signal VPOR to the H level and criterion voltage Vpr can thus be made uniform in spite of difference in voltage change rate.

Thus, according to the power on reset circuit according to the first embodiment, even when the voltage change rate at the time of rise of the supply voltage varies, the POR signal can be generated at appropriate timing without increase in power consumption. Since the transistor connected in series to the voltage division resistor and the latch circuit in the subsequent stage as in PTL 1 are not arranged, the POR signal can quickly be generated. As shown in FIG. 12, even when the voltage change rate is different, the level of supply voltage AVDD at the time of actual transition of output signal VPOR to the H level is comparable. Therefore, operations at the time of activation of the semiconductor device on which the power on reset circuit is mounted can be stabilized.

### Second Embodiment

The exemplary preferred configuration of the voltage rate detection circuit will be described in the second embodiment.

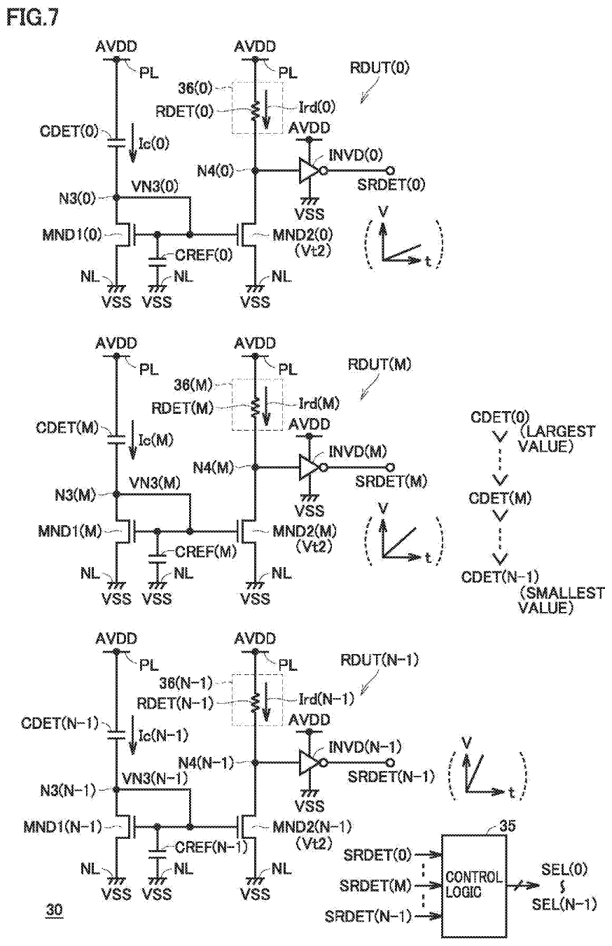

FIG. 7 is a circuit diagram illustrating the exemplary configuration of the voltage rate detection circuit according to the second embodiment.

Referring to FIG. 7, voltage rate detection circuit 30 includes N rate detection units RDUT(0)~RDUT(N−1) and a control logic 35.

Rate detection units RDUT(0)~RDUT(N−1) output rate detection signals SRDET(0)~SRDET(N−1), respectively, based on the voltage change rate of supply voltage AVDD. Control logic 35 generates selection signals SEL(0)~SEL(N−1) in FIG. 1, in accordance with rate detection signals SRDET(0)~SRDET(N−1).

Though FIG. 7 illustrates rate detection units RDUT(0), RDUT(M), and RDUT(N−1), they are similar in circuit configuration and different only in a part of a circuit constant as will be described later. A configuration of an Mth rate detection unit RDUT(M) will representatively be described.

Rate detection unit RDUT(M) includes a detection capacitor CDET(M), a charging capacitor CREF(M), transistors MND 1(M) and MND 2(M), a current supply circuit 36(M), and an inverter INVD(M).

Detection capacitor CDET(M) is connected between power supply line PL and a node N3(M) and transistor MND1(M) is connected between node N3(M) and ground line NL. Transistor MND2(M) is connected between a node N4(M) and ground line NL. Transistors MND1(M) and MND2(M) have their gates connected to node N3(M), and charging capacitor CREF(M) is connected between node N3(M) and ground line NL. In other words, transistor MND1(M) is diode-connected.

Charging capacitor CREF(M) includes at least a gate capacitance (parasitic capacitance) of transistor MND2(M), and it may be implemented with a parallel plate capacitor, a metal oxide semiconductor (MOS) capacitor, or the like being additionally connected thereto. A capacitance value of each capacitor will also herein be denoted with the same reference character below.

Current supply circuit 36(M) is connected between power supply line PL and node N4(M) to supply the current to node N4(M). In the example in FIG. 7, current supply circuit 36(M) includes a resistive element RDET(M) connected between power supply line PL and node N4(M). In other words, a supply current Ird(M) supplied by current supply circuit 36(M) is adjusted based on a resistance value of resistive element RDET(M), and as RDET(M) is lower, supply current Ird(M) is larger.

Inverter INVD(M) outputs rate detection signal SRDET(M) having the logic level in accordance with the voltage of node N4(M). The voltage of node N4(M) is supply voltage AVDD while transistor MND2(M) is off, and it changes to ground voltage VSS at a rate in accordance with supply current Ird(M) in response to turn-on of transistor MND2(M). Therefore, rate detection signal SRDET(M) is at the L level (ground voltage VSS) while transistor MND2(M) is off, whereas it makes transition from the L level to the H level in response to turn-on of transistor MND2(M).

Operations of rate detection unit RDUT(M) in response to input of supply voltage AVDD will now be described.

As a voltage Vc applied to a capacitor having a capacitance value C changes, a current Ic=C●dVc/dt is produced in the capacitor. Therefore, in accordance with voltage change rate VRT [V/s] (VRT=dAVDD/dt) which represents a rate of change over time in supply voltage AVDD applied to detection capacitor CDET(M), a detection current Ic(M) in accordance with an expression (2) below is produced in detection capacitor CDET(M). As is understood from the expression (2), detection current Ic(M) is larger as detection capacitor CDET(M) is larger, and it is larger as voltage change rate VRT is higher.

Ic(M)=CDET(M)●VRT . . . (2)

At the time of rise of supply voltage AVDD, charging capacitor CREF(M) at node N3(M) is charged with detection current Ic(M) produced in accordance with change in supply voltage AVDD. As the voltage of node N3(M) becomes higher than a threshold voltage Vt2 of transistor MND2(M) owing to charging, transistor MND2(M) turns on and rate detection signal SRDET(M) makes transition from the L level to the H level. Rate detection signal SRDET(M) is thus generated.

Rate detection units RDUT(0)~RDUT(N−1) are different from one another in capacitance ratio Kc of detection capacitors CDET(0)~CDET(N−1) to charging capacitors CREF(0)~CREF(N−1). In FIG. 7, a condition of CDET(0)/CREF(0)<. . . <CDET(M)/CREF(M)<. . . <CDET(N−1)/CREF(N−1) is satisfied, and capacitance ratio Kc is designed to be higher in rate detection unit RDUT on the lower-order bit side. An element constant other than capacitance ratio Kc is set in common among rate detection units RDUT(0)~RDUT(N−1). In other words, threshold voltage Vt2 is also common among transistors MND2(0)~MND2(N−1).

An example in which, in order to achieve capacitance ratio Kc, the capacitance values of charging capacitors CREF(0)~CREF(N−1) are in common among rate detection units RDUT(0)~RDUT(N−1) whereas the capacitance values of detection capacitors CDET(0)~CDET(N−1) are stepwise larger in rate detection unit RDUT on the lower-order bit side will be described below. In other words, a condition of CDET(0)<. . . <CDET(M)<. . . <CDET(N−1) is satisfied. The capacitance values of detection capacitors CDET(0)~CDET(N−1) can stepwise be set, for example, such that the capacitance value decreases by (½) time in accordance with a factorial of two.

In the exemplary configuration in FIG. 7, transistor MND2 of each rate detection unit RDUT corresponds to one example of the “second transistor,” node N3 corresponds to one example of the “third node,” and node N4 corresponds to one example of the “fourth node.” Transistor MND2, current supply circuit 36, and inverter INVD can implement one example of the “rate determination circuit” for generating rate detection signal SRDET.

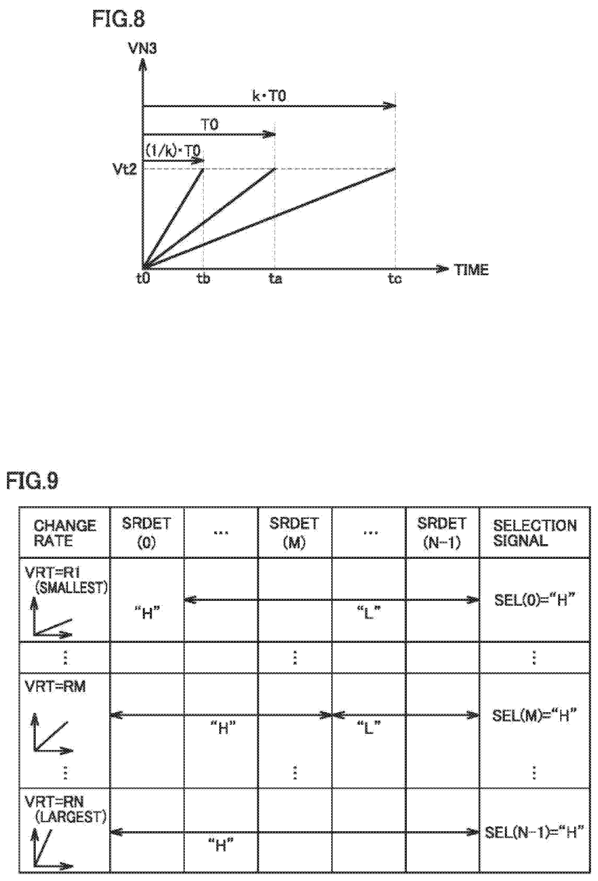

FIG. 8 is a conceptual waveform diagram illustrating an operation of the voltage rate detection circuit. The ordinate in FIG. 8 represents a voltage VN3 of node N3.

Referring to FIG. 8, detection currents Ic(0)~Ic(N−1) produced in rate detection units RDUT(0)~RDUT(N−1) at the time of rise of supply voltage AVDD at time to are in proportion to the capacitance values of detection capacitors CDET(0)~CDET(N−1), respectively.

In the example in FIG. 8, in one rate detection unit RDUT, at time ta after lapse of T0 since time t0, voltage VN3 of node N3 reaches threshold voltage Vt2 of transistors MND2(0)~MND2(N−1). In this case, as compared with that rate detection unit RDUT, in rate detection unit RDUT where the capacitance value of detection capacitor CDET is k times (k: real number) larger, at time tb after lapse of (TO/k) since time t0, voltage VN3 reaches threshold voltage Vt2 before time ta. In contrast, it is understood that, in rate detection unit RDUT where the capacitance value of detection capacitor CDET is (1/k) time larger, at time tc after lapse of (k●TO) since time t0, voltage VN3 reaches threshold voltage Vt2 after time ta.

Therefore, with a smallest rate value and a largest rate value of a range of detection of the voltage change rate of supply voltage AVDD being determined in advance, the capacitance value (or capacitance ratio Kc) of detection capacitor CDET is set such that the voltage of node N3 increases to threshold voltage Vt2 within a predetermined reference time period at the time of application of supply voltage AVDD having the smallest rate value in rate detection unit RDUT(0) where the capacitance value (that is, capacitance ratio Kc) of detection capacitor CDET is largest.

In contrast, the capacitance value (or capacitance ratio Kc) of detection capacitor CDET is set such that the voltage of node N3 increases to threshold voltage Vt2 within the same reference time period at the time of application of supply voltage AVDD having the largest rate value in rate detection unit RDUT(N−1) where the capacitance value (that is, capacitance ratio Kc) of detection capacitor CDET is smallest.

Furthermore, in intermediate rate detection units RDUT(1)~RDUT(N−2), in a range between rate detection units RDUT(0) and RDUT(N−1), the capacitance value (or capacitance ratio Kc) of detection capacitor CDET is stepwise set to be smaller on the higher-order bit side. Rate detection signals SRDET(0)~SRDET(N−1) from respective rate detection units RDUT(0)~RDUT(N−1) are thus generated as shown in FIG. 9.

FIG. 9 shows a chart illustrating the operation of the voltage rate detection circuit shown in FIG. 7.

Referring to FIG. 9, as supply voltage AVDD having a smallest rate value R1 is inputted to rate detection units RDUT(0)~RDUT(N−1), at a time point of lapse of the reference time period since sensing of rise of supply voltage AVDD based on the voltage on power supply line PL, transistor MND2(0) turns on only in rate detection unit RDUT(0) where the capacitance value (that is, capacitance ratio Kc) of detection capacitor CDET is largest. In other rate detection units RDUT(1)~RDUT(N−1), on the other hand, transistors MND2(1)~MND2(N−1) remain off. Consequently, at the time of lapse of the reference time period, rate detection signal SRDET(0) is at the H level, whereas rate detection signals SRDET(1)~SRDET(N−1) are at the L level. In other words, rate detection signal SRDET is generated only in rate detection unit RDUT(0).

As supply voltage AVDD, voltage change rate VRT of which has a rate value RM between smallest rate value R1 and a largest rate value RN, is inputted to rate detection units RDUT(0)~RDUT(N−1), transistors MND2(0)~MND2(M) turn on in rate detection units RDUT(0)~RDUT(M) at the time of lapse of the reference time period. On the other hand, transistors MND2(M+1)~MND2(N−1) remain off in rate detection units RDUT(M+1)~RDUT(N−1) on the high-order bit side of the former and being smaller in capacitance value (that is, capacitance ratio Kc) of detection capacitor CDET than rate detection unit RDUT(M). Consequently, at the time of lapse of the reference time period, rate detection signals SRDET(0)~SRDET(M) are at the H level whereas rate detection signals SRDET(M+1)~SRDET(N−1) are at the L level. In other words, rate detection signal SRDET is generated in (M+1) rate detection units RDUT(0)~RDUT(M).

As the voltage change rate of supply voltage AVDD is thus higher than smallest rate value R1, the number of rate detection units RDUT which generate rate detection signal SRDET in response to turn-on of transistor MND2 increases from the lower-order bit side at the time of lapse of the reference time period.

As supply voltage AVDD having largest rate value RN is inputted to rate detection units RDUT(0)~RDUT(N−1), transistor MND2(N−1) turns on also in rate detection unit RDUT(N−1) where the capacitance value (that is, capacitance ratio Kc) of detection capacitor CDET is smallest at the time of lapse of the reference time period. Therefore, at the time of lapse of the reference time period, all of rate detection signals SRDET(0)~SRDET(N−1) attain to the H level. Rate detection signal SRDET is generated in N rate detection units RDUT(0)~RDUT(N−1).

Control logic 35 sets only one of selection signals SEL(0)~SEL(N−1) to the H level and sets other (N−1) selection signals to the L level in accordance with rate detection signals SRDET(0)~SRDET(N−1) generated as described above.

Specifically, control logic 35 can be constructed such that, in correspondence with the bit on the highest-order side among bits set to the H level of rate detection signals SRDET(0)~SRDET(N−1), only corresponding one bit of selection signal SEL is set to the H level. When all of rate detection signals SRDET(0)~SRDET(N−1) are at the L level, selection signal SEL(0) is set to the H level.

As selection signals SEL(0)~SEL(N−1) thus generated are inputted to voltage dividing circuit 10 and voltage determination circuit 20 described in the first embodiment, power on reset circuit 5 can operate in accordance with the equivalent circuit diagram shown in FIG. 6.

According to voltage rate detection circuit 30 described in the second embodiment, the voltage change rate can quickly be detected in a plurality of stages (N stages) at the time of rise of supply voltage AVDD with a simplified configuration.

Supply currents Ird(0)~Ird(N−1) supplied by current supply circuits 36(0)~36(N−1) can also be set to values different among rate detection units RDUT(0)~RDUT(N−1) shown in FIG. 7. Specifically, since rate detection unit RDUT on the higher-order bit side is arranged to detect the relatively high voltage change rate, a condition of Ird(0)<. . . <Ird(M)<. . . <~Ird(N−1) is preferably set such that supply current Ird is larger on the higher-order bit side.

In the example in FIG. 7, the resistance value of resistive element RDET is set to satisfy a condition of RDET(0)>. . . >RDET(M)>. . . >RDET(N−1), so that such setting of supply currents Ird(0)~Ird(N−1) can be made. In FIG. 7, each of resistive elements RDET(0)~RDET(N−1) corresponds to one example of the “fourth resistive element.”

In FIGS. 7 and 5, in connection with threshold voltage Vt1 of transistor 21 of voltage determination circuit 20 and threshold voltage Vt2 of transistor MND2 of each rate detection unit RDUT, threshold voltage Vt1 (transistor 21) is preferably set to be higher than threshold voltage Vt2 (transistor MND2) (Vt1 >Vt2). In other words, the voltage of node N1 at the time of turn-on of transistor 21 is preferably higher than the voltage of node N3 at the time of turn-on of transistor MND2. Thus, such a malfunction of power on reset circuit 5 as erroneous generation of the POR signal (that is, output signal VPOR erroneously making transition from the L level to the H level) can be suppressed and operations can be more reliable.

### Third Embodiment

A modification of the configuration of the voltage determination circuit and the voltage rate detection circuit illustrated in the first and second embodiments will be described in a third embodiment.

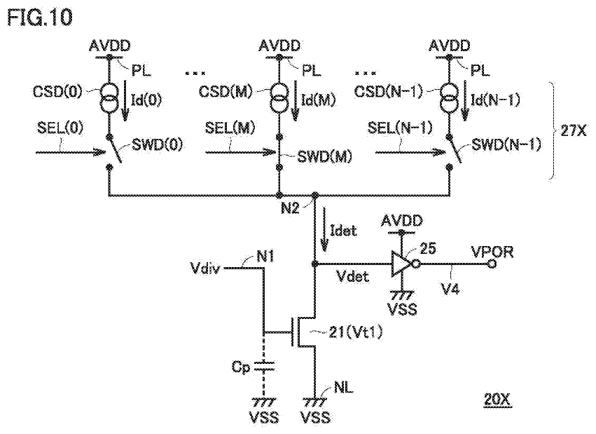

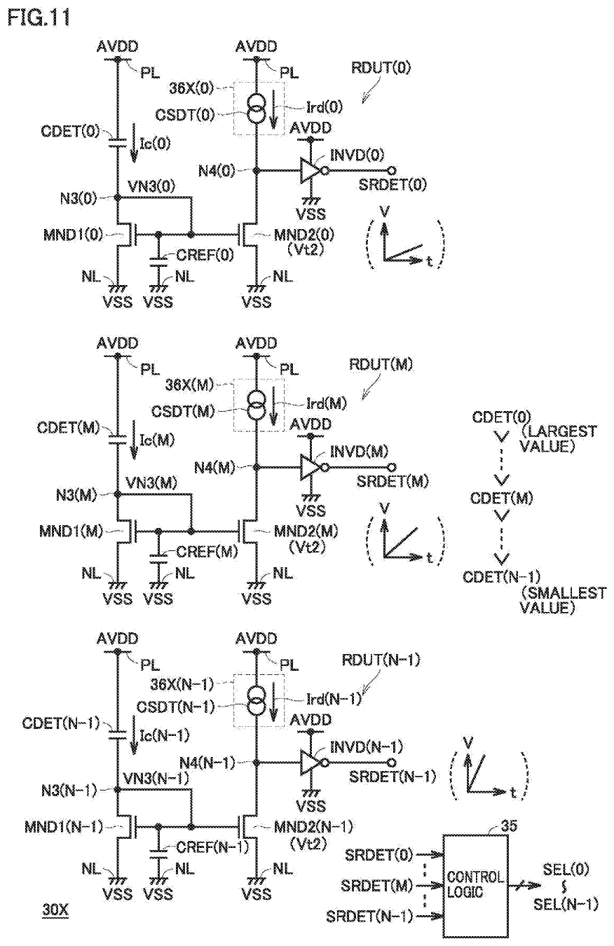

FIG. 10 is a circuit diagram illustrating an exemplary configuration of a voltage determination circuit according to the third embodiment.

Referring to FIG. 10, a voltage determination circuit 20X according to the third embodiment is different from voltage determination circuit 20 shown in FIG. 5 in including a current control circuit 27X instead of current control circuit 27.

Current control circuit 27X is different from current control circuit 27 in including current source circuits CSD(0)~CSD(N−1) including transistors instead of resistive elements RD(0)~RD(N−1), respectively. Current control circuit 27X is otherwise similar in configuration to current control circuit 27. Specifically, current control circuit 27X includes current source circuits CSD(0)~CSD(N−1) and switch elements SWD(0)~SWD(N−1) connected in parallel between power supply line PL and node N2. Switch elements SWD(0)~SWD(N−1) are connected in series to respective current source circuits CSD(0)~CSD(N−1), between power supply line P1 and Node N2.

Output currents Id(0)~Id(N−1) from current source circuits CSD(0)~CSD(N−1) are different from one another. Specifically, the output currents are set to be larger on the higher-order bit side or to satisfy a condition of Id(0)<Id(1)<. . . Id(M) . . . <Id(N−1). Switch elements SWD(0)~SWD(N−1) turn on and off as described in the first embodiment, in accordance with selection signals SEL(0)~SEL(N−1), respectively. Therefore, current source circuit CSD larger in output current as the voltage change rate detected by voltage rate detection circuit 30 is higher is connected by switch element SWD, between power supply line PL and node N2.

Consequently, as in the first embodiment, as the voltage change rate detected by voltage rate detection circuit 30 is higher, supply current Idet from current control circuit 27X to node N2 can be larger. A rate of change in voltage of node N2 at the time of turn-on of transistor 21 can thus be increased.

Therefore, power on reset circuit 5 as described in the first embodiment can be realized also with voltage determination circuit 20X shown in FIG. 10. In FIG. 10, each of current source circuits CSD(0)~CSD(N−1) corresponds to one example of the “first current source circuit.”

FIG. 11 is a circuit diagram illustrating an exemplary configuration of a voltage rate detection circuit according to the third embodiment.

Referring to FIG. 11, a voltage rate detection circuit 30X according to the third embodiment is different from voltage rate detection circuit 30 shown in FIG. 7 in that rate detection units RDUT(0)~RDUT(N−1) include current supply circuits 36X(0)~36X(N−1) instead of current supply circuits 36(0)~36(N−1), respectively.

Current supply circuits 36X(0)~36X(N−1) are different in including current source circuits CSDT(0)~CSDT(N−1) including transistors (not shown) instead of resistive elements RD(0)~RD(N−1), respectively. Voltage rate detection circuit 30X is otherwise similar in configuration to voltage rate detection circuit 30.

As described in the last part of the second embodiment, supply currents Ird(0)~Ird(N−1) supplied by current supply circuits 36(0)~36(N−1) are preferably set such that supply current Ird is larger in rate detection unit RDUT on the higher-order bit side or to satisfy the condition of Ird(0)<. . . <Ird(M)<. . . <~Ird(N−1). In the configuration in FIG. 11, the output currents from current source circuits CSDT(0)~CSDT(N−1) are designed such that the output current is larger in rate detection unit RDUT on the higher-order bit side. Thus, such setting of supply currents Ird(0)~Ird(N−1) can be made. In FIG. 11, each of current source circuits CSDT(0)~CSDT(N−1) corresponds to one example of the “second current source circuit.” In the exemplary configuration in FIG. 11, transistor MND2, current supply circuit 36X, and inverter INVD implement one example of the “rate determination circuit” for generation of rate detection signal SRDET.

It should be understood that the embodiments disclosed herein are illustrative and non-restrictive in every respect. The scope of the present disclosure is defined by the terms of the claims rather than the description above and is intended to include any modifications within the scope and meaning equivalent to the terms of the claims.

### REFERENCE SIGNS LIST

5, 5# power on reset circuit; 10, 10# voltage dividing circuit; 15 selection circuit; 20, 20X, 20# voltage determination circuit; 21, MND 1(0)~MND1(N−1), MND 2(0)~MND2(N−1) transistor; 22, 36, 36X current supply circuit; 25 signal generation circuit; 27, 27X current control circuit; 30, 30X voltage rate detection circuit; 35 control logic; AVDD supply voltage; CDET(0)~CDET(N−1) detection capacitor; CREF(0)~CREF(N−1) charging capacitor; CSD(0)~CSD(N−1), CSDT(0)~CSDT(N−1) current source circuit; INVD(0)~INVD(N−1) inverter; Ic(0)~Ic(N−1) detection current; Id(0)~Id(N−1) output current (current source circuit); Idet(0)~Idet(N−1), Ird(0)~Ird(N−1) supply current; N1~N4 node; NL reference voltage line (ground line); PL power supply line; RD(0)~RD(N−1), RDET(0)~RDET(N−1), RH(0)~RH(N−1), RL(0)~RL(N−1) resistive element; RDUT(0)~RDUT(N−1) rate detection unit; SEL(0)~SEL(N−1) selection signal; SRDET(0)~SRDET(N−1) rate detection signal; SWD(0)~SWD(N−1), SWH(0)~SWH(N−1), SWL(0)~SWL(N−1) switch element; VPOR output signal; VRT voltage change rate; VSS reference voltage (ground voltage); Vdiv divided voltage; Vt1, Vt2 threshold voltage; Vpr criterion voltage.

1. A power on reset circuit comprising:
a power supply line supplied with a supply voltage;
a reference voltage line through which a reference voltage is transmitted;
a voltage dividing circuit connected between the power supply line and the reference voltage to output a divided voltage of the supply voltage to a first node;
a voltage rate detection circuit to detect a voltage change rate of the supply voltage at time of rise of the supply voltage; and
a voltage determination circuit to generate an output signal indicating a result of comparison between a voltage of the first node and a predetermined voltage, wherein the voltage dividing circuit is configured to maintain constant, a voltage division ratio of the divided voltage to the supply voltage and to variably set an impedance between the power supply line and the reference voltage, in accordance with the voltage change rate detected by the voltage rate detection circuit, and the impedance is set to be lower as the voltage change rate is higher.

2. The power on reset circuit according to claim 1, wherein
the voltage determination circuit comprises
a current control circuit connected between the power supply line and a second node to variably control a supply current supplied from the power supply line to the second node in accordance with the voltage change rate detected by the voltage rate detection circuit, and
a first transistor connected between the second node and the reference voltage line to turn on and off in accordance with the voltage of the first node,
the output signal is generated to have a logic level in accordance with a voltage of the second node that changes with turn-on and -off of the first transistor, and
the current control circuit controls the supply current to be larger as the voltage change rate is higher.

3. The power on reset circuit according to claim 2, wherein
the current control circuit comprises
a plurality of first resistive elements connected in parallel between the power supply line and the second node, and
a plurality of switch elements connected in series to the plurality of first resistive elements, respectively, between the power supply line and the second node, and
turn-on and -off of the plurality of switch elements is controlled such that an electrical resistance value between the power supply line and the second node is smaller as the voltage change rate is higher, in accordance with the voltage change rate detected by the voltage rate detection circuit.

4. The power on reset circuit according to claim 2, wherein
the current control circuit comprises
a plurality of first current source circuits connected in parallel between the power supply line and the second node, the plurality of first current source circuits each including a transistor, and
a plurality of switch elements connected in series to the plurality of first current source circuits, respectively, between the power supply line and the second node, and
turn-on and -off of the plurality of switch elements is controlled such that the supply current supplied by the plurality of first current source circuits is larger as the voltage change rate is higher, in accordance with the voltage change rate detected by the voltage rate detection circuit.

5. The power on reset circuit according to claim 1, wherein
the voltage dividing circuit comprises
a plurality of voltage division resistors, and
a selection circuit to selectively connect the plurality of voltage division resistors between the power supply line and the reference voltage line in accordance with the voltage change rate detected by the voltage rate detection circuit,
each of the plurality of voltage division resistors comprises
a second resistive element connected between the power supply line and the first node, and
a third resistive element connected between the reference voltage line and the first node,
a ratio between electrical resistance values of the second resistive element and the third resistive element is common among the plurality of voltage division resistors, whereas a sum of the electrical resistance values of the second resistive element and the third resistive element is different among the plurality of voltage division resistors, and
the selection circuit is controlled such that an electrical resistance values of value between the power supply line and the reference voltage line are smaller as the voltage change rate is higher.

6. The power on reset circuit according to claim 1, wherein
the voltage rate detection circuit comprises N rate detection units,
the N is an integer not smaller than two,
each of the N rate detection units comprises
a detection capacitor connected between the power supply line and a third node, and
a rate determination circuit to generate a rate detection signal in response to a voltage of the third node becoming higher than a predetermined voltage,
a ratio of a capacitance value of the detection capacitor to a capacitance value of the third node is different among the N rate detection units,
the voltage rate detection circuit detects the voltage change rate in N stages based on the number of rate detection units which have generated the rate detection signals among the N rate detection units, at a time point of lapse of a predetermined reference time period since rise of the supply voltage, and
a large voltage change rate is detected as the number is larger.

7. The power on reset circuit according to claim 6, wherein
the rate determination circuit comprises
a current supply circuit connected between the power supply line and a fourth node to supply a current from the power supply line to the fourth node, and
a second transistor connected between the fourth node and the reference voltage line to turn on and off in accordance with the voltage of the third node,
the rate detection signal is generated as a voltage of the fourth node changes with turn-on of the second transistor,
a supply current supplied by the current supply circuit is different among the N rate detection units, and
a large supply current is set in a rate detection unit smaller in capacitance value of the detection capacitor.

8. The power on reset circuit according to claim 1, wherein
the voltage determination circuit comprises
a current control circuit connected between the power supply line and a second node to control a supply current from the power supply line to the second node, and
a first transistor connected between the second node and the reference voltage line to turn on and off in accordance with the voltage of the first node,
the output signal is generated to have a logic level in accordance with a voltage of the second node that changes with turn-on and -off of the first transistor,
the voltage rate detection circuit comprises N rate detection units, the N is an integer not smaller than two,
each of the N rate detection units comprises
a detection capacitor connected between the power supply line and a third node, and
a current supply circuit connected between the power supply line and a fourth node to supply a current from the power supply line to the fourth node, and
a second transistor connected between the fourth node and the reference voltage line to turn on and off in accordance with a voltage of the third node, and
generates a rate detection signal as a voltage of the fourth node changes with turn-on of the second transistor,
a ratio of a capacitance value of the detection capacitor to a capacitance value of the third node is different among the N rate detection units,
the voltage rate detection circuit detects the voltage change rate in N stages based on the number of rate detection units which have generated the rate detection signals among the N rate detection units, at a time point of lapse of a predetermined reference time period since rise of the supply voltage, and
the voltage of the first node at time of turn-on of the first transistor is higher than the voltage of the third node at the time of turn-on of the second transistor.

9. The power on reset circuit according to claim 7, wherein
the current supply circuit comprises a fourth resistive element connected between the power supply line and the fourth node, an electrical resistance value of the fourth resistive element being different among the N rate detection units, and
a smaller electrical resistance value is set in a rate detection unit smaller in capacitance value of the detection capacitor.

10. The power on reset circuit according to claim 7, wherein
the current supply circuit comprises a second current source circuit connected between the power supply line and the fourth node, an output current from the second current source circuit being different among the N rate detection units, and
the output current from the second current source circuit is larger in a rate detection unit smaller in capacitance value of the detection capacitor.

11. The power on reset circuit according to claim 7, wherein
among the N rate detection units, a capacitance value of the third node is common whereas the capacitance value of the detection capacitor is different.
